(19) United States
(12) Patent Application Publication
(10) Pub. No.: US 2025/0210440 A1
(43) Pub. Date: Jun. 26, 2025

(54) SEMICONDUCTOR PACKAGE AND MANUFACTURING METHOD FOR THE SAME

(71) Applicant: Samsung Electronics Co., Ltd., Suwon-si (KR)

(72) Inventors: Minjung KIM, Suwon-si (KR); Mira KIM, Suwon-si (KR); Yunjeong KIM, Suwon-si (KR); Se Un CHO, Suwon-si (KR); Jung-Sang CHOI, Suwon-si (KR); Sujin HONG, Suwon-si (KR)

(73) Assignee: Samsung Electronics Co., Ltd., Suwon-si (KR)

(21) Appl. No.: 18/770,834

(22) Filed: Jul. 12, 2024

(30) Foreign Application Priority Data
Dec. 20, 2023 (KR) 10-2023-0187542

(51) Int. Cl. H01L 23/36; H01L 21/48; H01L 23/00; H01L 23/053; H01L 23/31; H01L 23/538; H01L 25/065; H10B 80/00

(52) U.S. Cl. CPC H01L 23/36; H01L 21/4882; H01L 23/5383; H01L 24/29; H01L 24/32; H01L 24/97; H01L 23/053; H01L 23/3107; H01L 24/16; H01L 24/33; H01L 24/73; H01L 25/0655; H01L 2224/16227; H01L 2224/2929; H01L 2224/29324; H01L 2224/29339; H01L 2224/29347; H01L 2224/29386; H01L 2224/32225; H01L 2224/32245; H01L 2224/33181; H01L 2224/33519; H01L 2224/73204; H01L 2224/95001; H10B 80/00

(57) ABSTRACT

A semiconductor package including a substrate; a semiconductor chip on the substrate and electrically connected to the substrate; a molding material on the substrate that molds the semiconductor chip; a thermal conductive adhesive on the semiconductor chip and the molding material; and a thermal conductive layer on the thermal conductive adhesive. A first surface of the thermal conductive layer faces the thermal conductive adhesive. A second surface of the thermal conductive layer which is opposite the first surface of the thermal conductive layer has a higher surface roughness value than the first surface.

### CROSS-REFERENCE TO RELATED APPLICATION

This application claims priority to and the benefit of Korean Patent Application No. 10-2023-0187542 filed in the Korean Intellectual Property Office on Dec. 20, 2023, the entire contents of which are incorporated herein by reference.

### BACKGROUND

The present disclosure relates to semiconductor packages and manufacturing methods of the same.

As semiconductor chips become more highly integrated and multifunctional, semiconductor chips consume more power and generate more heat. Heat generated from a semiconductor chip must be effectively dissipated outside the package to reduce thermal expansion, and improve device performance, reliability and lifespan. For example, in order to improve heat dissipation characteristics, a heat dissipation layer may sometimes be attached to the completed semiconductor package using thermal paste. As a result however, the manufacturing process becomes complicated, requiring time and cost for additional processes, and additional process risks may occur.

### SUMMARY

Some example embodiments of the inventive concepts provide a semiconductor package with improved heat dissipation characteristics, and a manufacturing method of the same.

Some example embodiments of the inventive concepts provide a semiconductor package capable of shortening the turnaround time (TAT) for manufacturing and reducing manufacturing costs through process simplification, and a manufacturing method of the same.

Some example embodiments of the inventive concepts provide a semiconductor package that includes a substrate; a semiconductor chip on the substrate, the semiconductor chip being electrically connected to the substrate; a molding material on the substrate, the molding material molding the semiconductor chip; a thermal conductive adhesive on the semiconductor chip and the molding material; and a thermal conductive layer on the thermal conductive adhesive, a first surface of the thermal conductive layer facing the thermal conductive adhesive. A second surface of the thermal conductive layer has a surface roughness value higher than a surface roughness value of the first surface of the thermal conductive layer, the first surface being opposite the second surface.

Some example embodiments of the inventive concepts further provide a semiconductor package that includes a substrate; a first semiconductor chip and a second semiconductor chip on the substrate, the first semiconductor chip and the second semiconductor chip being spaced apart from each other; a molding material on the substrate, the molding material molding the first semiconductor chip and the second semiconductor chip; a thermal conductive adhesive on the first semiconductor chip, the second semiconductor chip, and the molding material; and a thermal conductive layer on the thermal conductive adhesive, a first surface of the thermal conductive layer facing the thermal conductive adhesive. The substrate electrically connects the first semiconductor chip and the second semiconductor chip to each other. A second surface of the thermal conductive layer has a surface roughness value higher than a surface roughness value of the first surface of the thermal conductive layer, the first surface being opposite the second surface.

Some example embodiments of the inventive concepts still further provide a manufacturing method of a semiconductor package that includes molding at least one semiconductor chip with a molding material, the at least one semiconductor chip being on a substrate, and the substrate being on a first carrier structure; attaching a second carrier structure on the at least one semiconductor chip and the molding material, the second carrier structure including a thermal conductive adhesive, a thermal conductive layer, an adhesive, and a base film sequentially stacked, and the thermal conductive adhesive is attached facing the semiconductor chip and the molding material; separating the first carrier structure from the substrate; and debonding the adhesive from the thermal conductive layer of the second carrier structure.

According to some example embodiments of the inventive concepts, a semiconductor package with improved heat dissipation characteristics, and a manufacturing method of the same may be provided.

According to some example embodiments of the inventive concepts, it is possible to provide a semiconductor package capable of shortening the turn around time (TAT) of manufacturing, and reducing manufacturing costs through process simplification, and a manufacturing method for the same.

### BRIEF DESCRIPTION OF THE DRAWINGS

FIG. 1 is a cross-sectional view of a semiconductor package according to some example embodiments of the inventive concepts.

FIG. 2 is an enlarged view of region A of FIG. 1.

FIG. 3 is a cross-sectional view of a package module including a semiconductor package according to some example embodiments of the inventive concepts.

FIG. 4 is a cross-sectional view of a semiconductor package according to some example embodiments of the inventive concepts.

FIG. 5 is a cross-sectional view of a semiconductor package according to some example embodiments of the inventive concepts.

FIG. 6 is a cross-sectional view of a semiconductor package according to some example embodiments of the inventive concepts.

FIGS. 7, 8, 9, 10, 11, 12, 13 and 14 are diagrams for describing a manufacturing process of a semiconductor package according to some example embodiments of the inventive concepts.

### DETAILED DESCRIPTION

Hereinafter, the inventive concepts will be described in detail with reference to the accompanying drawings, in which some example embodiments are shown. As those skilled in the art would realize, the described example embodiments may be modified in various different ways, all without departing from the spirit or scope of the inventive concepts.

The drawings and description are to be regarded as illustrative in nature and not restrictive. Like reference numerals designate like elements throughout the specification.

Size and thickness of each constituent element in the drawings are arbitrarily illustrated for better understanding and ease of description, and the example embodiments are not limited thereto. In the drawings, the thickness of layers, films, panels, regions, etc., are exaggerated for clarity. In the drawings, the thickness of some layers and regions may be exaggerated for ease of description.

Throughout the specification, the term “coupled” does not mean only “directly coupled”, but also mean “indirectly coupled” with another element in between. In a similar perspective, this includes not only cases where it is “physically coupled”, but also those where it is “electrically coupled.”

Unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity.

Throughout the specification, the phrase “on a plane” and/or “planar” means a view from a position above the object (e.g., from the top), and the phrase “on a cross-section” and/or “cross-sectional” means a view of a cross-section of the object which is vertically cut from the side.

Throughout the specification, although terms “first,” “second,” and the like are used to explain various constituent elements, the constituent elements are not limited to such terms. These terms are only used to distinguish one constituent element from another constituent element. Accordingly, a configuration referred to as the first constituent element in a certain part of the specification may also be referred to as the second constituent element in other parts of the specification.

As used herein, the singular forms are intended to include the plural forms unless the context clearly indicates otherwise. For example, “insulating layer” may be used to mean not just a single insulating layer, but a plurality of insulating layers, such as two, three, or more.

Throughout the specification, references to first surface and second surface are intended to distinguish different surfaces from each other, and are not necessarily intended to limit them to a specific surface. Accordingly, the side referred to as first surface in a specific part of this specification may be referred to as second surface in other parts of this specification.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, a semiconductor package according to some example embodiments of the inventive concepts will be described with reference to the drawings.

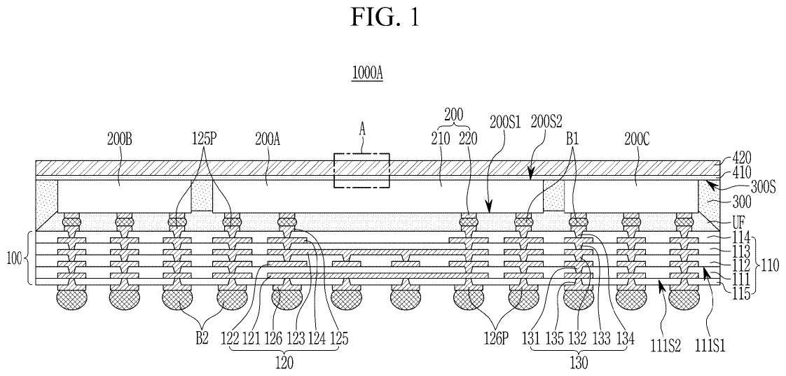

FIG. 1 is a cross-sectional view of a semiconductor package according to some example embodiments of the inventive concepts.

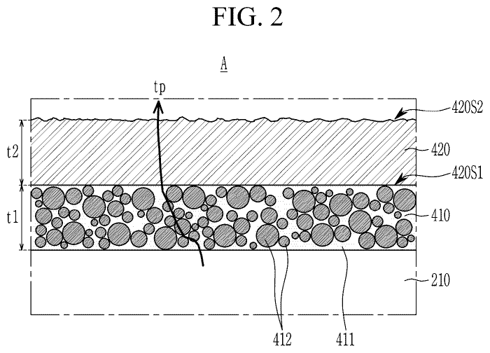

FIG. 2 is an enlarged view of region A of FIG. 1.

Referring to the drawings, a semiconductor package 1000A may include a substrate 100, at least one semiconductor chip 200, a molding material 300, a thermal conductive adhesive 410, and a thermal conductive layer 420.

The substrate 100 may be an interposer substrate that electrically connects semiconductor chips 200A, 200B, and 200C disposed on the substrate 100 to each other. For example, the substrate 100 may electrically connect two or more of the first semiconductor chip 200A, the second semiconductor chip 200B, and the third semiconductor chip 200C. In a semiconductor package including an interposer substrate 100 that electrically connects a plurality of semiconductor chips 200 to each other, further improvement in heat dissipation characteristics may be required.

The substrate 100 may include a plurality of insulating layers 110, a plurality of wiring layers 120, and a plurality of vias 130.

For example, the substrate 100 may include a first wiring layer 121, a first insulating layer 111 covering the first wiring layer 121, a second wiring layer 122 disposed on a first surface 111S1 of the first insulating layer 111, a second insulating layer 112 disposed on the first surface 111S1 of the first insulating layer 111 to cover the second wiring layer 122, a third wiring layer 123 disposed on the second insulating layer 112, a third insulating layer 113 disposed on the second insulating layer 112 to cover the third wiring layer 123, a fourth wiring layer 124 disposed on the third insulating layer 113, a fourth insulating layer 114 disposed on the third insulating layer 113 to cover the fourth wiring layer 124, a fifth wiring layer 125 disposed on the fourth insulating layer 114, a fifth insulating layer 115 disposed on a second surface 111S2 of the first insulating layer 111 to cover the first wiring layer 121, and a sixth wiring layer 126 disposed on the fifth insulating layer 115.

The substrate 100 may include first vias 131 that electrically connect the first wiring layer 121 and the second wiring layer 122 through the first insulating layer 111, second vias 132 that electrically connect the second wiring layer 122 and the third wiring layer 123 through the second insulating layer 112, third vias 133 that electrically connect the third wiring layer 123 and the fourth wiring layer 124 through the third insulating layer 113, fourth vias 134 that electrically connect the fourth wiring layer 124 and the fifth wiring layer 125 through the fourth insulating layer 114, and fifth vias 135 that electrically connect the first wiring layer 121 and the sixth wiring layer 126 through the fifth insulating layer 115.

However, the number of insulating layers 110 and wiring layers 120 included in the substrate 100 is not limited to the number shown in the drawing, and the substrate 100 may include more or fewer insulating layers 110 and wiring layers 120.

The insulating layer 110 may insulate the wiring layers 120 disposed on different layers from each other.

The material of the insulating layer 110 may be an insulating material, for example, a thermoplastic resin such as polyimide, a thermosetting resin such as epoxy, prepreg (PPG), or the like.

The wiring layer 120 may perform various roles depending on the design, and may include a signal pattern, a power pattern, a ground pattern, etc.

The fifth wiring layer 125 and the sixth wiring layer 126 positioned on the outermost sides of the wiring layer 120 may include a first connection pad 125P and a second connection pad 126P. The semiconductor chip 200 may be electrically connected to the wiring layers 120 of the substrate 100 through the first connection pad 125P. A conductive bump B2 may be disposed on the second connection pad 126P. The semiconductor package 1000A may be mounted on a printed circuit board (PCB), such as a main board, through the conductive bump B2, and may be electrically connected to the printed circuit board.

The material for the wiring layer 120 may be a conductive material, such as aluminum (AI), copper (Cu), gold (Au), silver (Ag), platinum (Pt), tin (Sn), chromium (Cr), palladium (Pd), lead (Pb), titanium (Ti), or alloys thereof.

The wiring layer 120 may include a plurality of metal layers, for example, a first metal layer that is a seed layer formed on the insulating layer 110, and a second metal layer that is a plating layer that is formed on the first metal layer.

The via 130 may electrically connect the wiring layers 120 positioned in different layers to each other.

The via 130 may have a tapered shape, a cylindrical shape, etc. whose diameter narrows in the direction from a first surface to a second surface. When the via 130 has a tapered shape, the vias 130 positioned in different layers may have a tapered shape in which the diameters narrow in the same direction, or may have a tapered shape in which the diameters narrow in opposite directions.

The same material as that of the wiring layer 120 may be used as the material for the via 130. The via 130 may also include a plurality of metal layers, for example, a first metal layer that is a seed layer formed on the wall of the via hole, and a second metal layer that is a plating layer that fills the via hole.

The via 130 may be formed integrally with the wiring layer 120 and may not have a boundary with the wiring layer 120. For example, the first vias 131 may be formed integrally with the second wiring layer 122, the second vias 132 may be formed integrally with the third wiring layer 123, the third vias 133 may be formed integrally with the fourth wiring layer 124, the fourth vias 134 may be formed integrally with the fifth wiring layer 125, and the fifth vias 135 may be formed integrally with the sixth wiring layer 126.

At least one semiconductor chip 200 may be disposed on the substrate 100 and electrically connected to the substrate 100.

At least one semiconductor chip 200 may be a plurality of semiconductor chips including a first semiconductor chip 200A, a second semiconductor chip 200B, and a third semiconductor chip 200C, which may be spaced apart from each other on the substrate 100. The first semiconductor chip 200A may be an application specific integrated circuit (ASIC) chip, and the second semiconductor chip 200B and the third semiconductor chip 200C may be high bandwidth memory (HBM) chips. However, the number and type of semiconductor chips 200 are not limited thereto and may be changed as needed.

Each semiconductor chip 200 may have a first surface 200S1 and a second surface 200S2, and may include a body 210 and a connection pad 220. The first surface 200S1 of the semiconductor chip 200 may be a surface on which the connection pad 220 is positioned and may be referred to as an active surface. The second surface 200S2 of the semiconductor chip 200 may be referred to as an inactive surface.

The body 210 may include a semiconductor substrate such as silicon, an internal circuit formed on the semiconductor substrate, an interlayer insulating layer, or the like. The connection pad 220 is electrically connected to the first connection pad 125P, thereby electrically connecting the semiconductor chip 200 to the substrate 100. The connection pad 220 may be formed of a conductive material such as copper (Cu) or aluminum (Al).

The semiconductor chip 200 may be disposed so that the connection pad 220 positioned on the first surface 200S1 faces the substrate 100. A conductive bump B1 may be disposed between the connection pad 220 of the semiconductor chip 200 and the first connection pad 125P of the substrate 100, and the conductive bump B1 may be covered with underfill resin UF.

The second surface 200S2 of the semiconductor chip 200 may be exposed to (e.g., at) a first surface 300S of the molding material 300 and covered with the thermal conductive adhesive 410. When the second surface 200S2 of the semiconductor chip 200 is exposed to the first surface 300S of the molding material 300, it is possible to have better heat dissipation characteristics than when the second surface 200S2 of the semiconductor chip 200 is covered with the molding material 300.

The second surface 200S2 of the semiconductor chip 200 and the first surface 300S of the molding material 300 may be coplanar. For example, the thermal conductive layer 420, which will be described later, may be more stably attached on the semiconductor chip 200 and the molding material 300 through the thermal conductive adhesive 410.

The molding material 300 may be disposed on the substrate 100 to mold the semiconductor chip 200. The molding material 300 may cover at least the side surface of the semiconductor chip 200.

As a material for the molding material 300, epoxy resin, epoxy molding compound (EMC), etc. may be used.

The thermal conductive adhesive 410 may be disposed on the semiconductor chip 200 and the molding material 300. As described above, the second surface 200S2 of the semiconductor chip 200 may be exposed to (e.g., at) the first surface 300S of the molding material 300, and the second surface 200S2 of the semiconductor chip 200 and the first surface 300S of the molding material 300 may be covered with the thermal conductive adhesive 410. For example, the second surface 200S2 of the semiconductor chip 200 may be exposed from the molding material 300 at a same level as the first surface 300S of the molding material 300, and the first surface 200S2 of the semiconductor chip 200 and the first surface 300S of the molding material 300 may be covered with the thermal conductive adhesive 410.

As a material for the thermal conductive adhesive 410, a material that has excellent adhesion to the body 210 and the molding material 300 of the semiconductor chip 200, and that has thermal conductivity may be used. The thermal conductive adhesive 410 may include a matrix resin 411 and a thermal conductive filler 412. The matrix resin 411 may include, for example, an acryl-based resin with excellent durability. The thermal conductive filler 412 may exist dispersed in the matrix resin 411, and the thermal conductive filler 412 particles adjacent to each other may form a heat dissipation path tp that transfers heat emitted from the semiconductor chip 200 to the thermal conductive layer 420. The thermal conductive filler 412 may include, for example, alumina (Al₂O₃), but is not limited thereto, and may also include a metal with high thermal conductivity such as copper, aluminum, or silver.

A thickness t1 of the thermal conductive adhesive 410 may be 10 μm to 50 μm. As will be described later, the thermal conductive adhesive 410 may be included in a tape-type carrier structure used during the manufacturing process of the semiconductor package 1000A, and may have a lower thickness than heat dissipation paste. Therefore, according to the present disclosure, it is possible to increase the thickness of the thermal conductive layer 420 compared to a semiconductor package of the same size, and improve the heat dissipation characteristics of the semiconductor package.

The thermal conductive layer 420 may be disposed on the heat conductive adhesive 410 so that a first surface 420S1 faces the heat conductive adhesive 410. The thermal conductive layer 420 may have a first surface 420S1 and a second surface 420S2, which are opposite to each other, and the first surface 420S1 of the thermal conductive layer 420 may be attached by directly contacting the thermal conductive adhesive 410. The thermal conductive layer 420 may be included in the carrier structure like the thermal conductive adhesive 410, and may cover the entire region of the thermal conductive adhesive 410.

The second surface 420S2 of the thermal conductive layer 420 may have a higher surface roughness (Ra) value than the first surface 420S1. The surface roughness (Ra) value of the second surface 420S2 of the thermal conductive layer 420 may be 5 to 17 times the surface roughness (Ra) value of the first surface 420S1. As will be described later, the second surface 420S2 of the thermal conductive layer 420 may be a surface on which the adhesive 430 is debonded, and may have a surface roughness (Ra) value increased by the debonding process. For example, the second surface 420S2 of the thermal conductive layer 420 may have an increased surface roughness (Ra) value compared to before the adhesive 430 is debonded by laser ablation, mechanical peeling, ultraviolet irradiation, or heat treatment. The surface roughness (Ra) value of the second surface 420S2 of the thermal conductive layer 420 may be 0.5 μm or more and 1.2 μm or less. The surface roughness (Ra) value of the first surface 420S1 of the thermal conductive layer 420 may be 0.03 μm or more and 0.2 μm or less.

A material with high thermal conductivity, such as metal, may be used as a material for the thermal conductive layer 420. For example, the thermal conductive layer 420 may include at least one of copper, aluminum, and stainless steel (SUS).

A thickness t2 of the thermal conductive layer 420 may be 10 μm to 200 μm. If the thickness t2 of the thermal conductive layer 420 is too low, the heat dissipation effect may be minimal, and if the thickness t2 of the thermal conductive layer 420 is too high, the entire thickness of the semiconductor package 1000A may increase. Therefore, it in some example embodiments the thickness t2 of the thermal conductive layer 420 may be within the above-mentioned range.

For heat dissipation characteristics, the thermal conductivity of the thermal conductive adhesive 410 and the thermal conductive layer 420 may be higher than the thermal conductivity of the semiconductor chip 200 and may be 148 W/mK or more.

In order to reduce (and/or minimize) warpage, in some example embodiments the thermal conductive adhesive 410 and the thermal conductive layer 420 to have a coefficient of thermal expansion (CTE) of 3 to 50 ppm/° C.

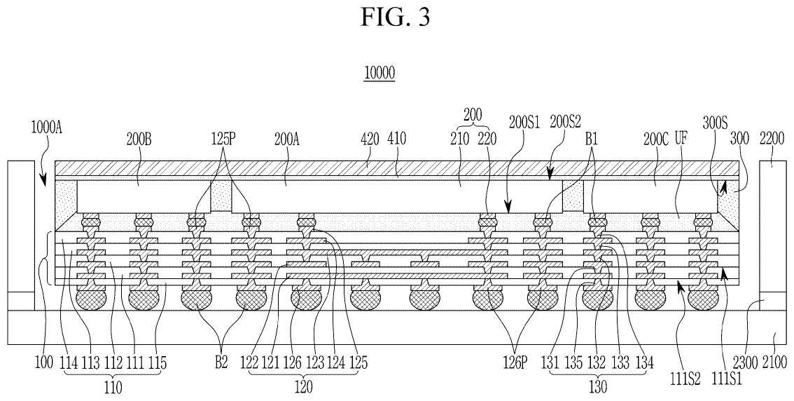

FIG. 3 is a cross-sectional view of a package module including a semiconductor package according to some example embodiments of the inventive concepts.

Referring to the drawings, a package module 10000 may include a semiconductor package 1000A, a substrate 2100 on which the semiconductor package 1000A is disposed, and a stiffener 2200 according to some example embodiments.

The substrate 2100 may be, for example, a printed circuit board such as a main board, and may include general components of a substrate such as an insulating layer, a wiring layer, and vias. The semiconductor package 1000A is mounted on the substrate 2100 through the conductive bump B2 and may be electrically connected to the substrate 2100.

The stiffener 2200 may be disposed on the substrate 2100 through an adhesive 2300 and may surround the semiconductor package 1000A. As a material for the stiffener 2200, a metal material such as copper may be used, and as a material for the adhesive 2300, any material capable of attaching the substrate 2100 and the stiffener 2200 to each other may be used without limitation.

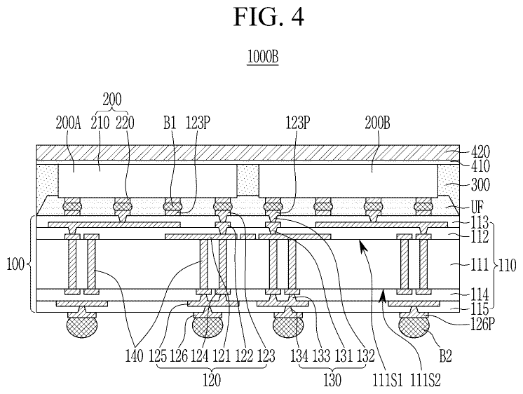

FIG. 4 is a cross-sectional view of a semiconductor package according to some example embodiments of the inventive concepts.

Referring to the drawings, the substrate 100 of a semiconductor package 1000B may include the first insulating layer 111, the first wiring layer 121 disposed on the first surface 111S1 of the first insulating layer 111, the second insulating layer 112 disposed on the first surface 111S1 of the first insulating layer 111 to cover the first wiring layer 121, the second wiring layer 122 disposed on the second insulating layer 112, the third insulating layer 113 disposed on the second insulating layer 112 to cover the second wiring layer 122, the third wiring layer 123 disposed on the third insulating layer 113, the fourth wiring layer 124 disposed on the second surface 111S2 of the first insulating layer 111, the fourth insulating layer 114 disposed on the second surface 111S2 of the first insulating layer 111 to cover the fourth wiring layer 124, the fifth wiring layer 125 disposed on the fourth insulating layer 114, the fifth insulating layer 115 disposed on the fourth insulating layer 114 to cover the fifth wiring layer 125, and the sixth wiring layer 126 disposed on the fifth insulating layer 115. The substrate 100 may include a through via 140 that electrically connects the first wiring layer 121 and the fourth wiring layer 124 by penetrating the first insulating layer 111, the first via 131 that electrically connects the second wiring layer 122 and the first wiring layer 121 by penetrating the second insulating layer 112, the second via 132 that electrically connects the third wiring layer 123 and the second wiring layer 122 by penetrating the third insulating layer 113, the third via 133 that electrically connects the fifth wiring layer 125 and the fourth wiring layer 124 by penetrating the fourth insulating layer 114, and the fourth via 134 that electrically connects the sixth wiring layer 126 and the fifth wiring layer 125 by penetrating the fifth insulating layer 115.

The first insulating layer 111 may be a silicon substrate formed by dicing a silicon wafer, and the second to fifth insulating layers 112, 113, 114, and 115 may be organic insulating layers. The first insulating layer 111 may have a greater thickness than the second to fifth insulating layers 112, 113, 114, and 115.

The substrate 100 may be an interposer substrate that electrically connects the first semiconductor chip 200A and the second semiconductor chip 200B disposed on the substrate 100.

Since the description of other components is the same as that described in the description of the semiconductor package 1000A according to some example embodiments of the inventive concepts, detailed description of these components will be omitted.

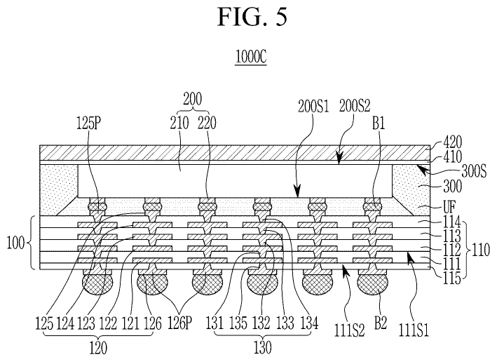

FIG. 5 is a cross-sectional view of a semiconductor package according to some example embodiments of the inventive concepts.

Referring to the drawings, a semiconductor package 1000C may include a single semiconductor chip 200, and the substrate 100 may be a redistribution layer substrate for redistributing the semiconductor chip 200.

Since the description of other components is the same as that described in the description of the semiconductor package 1000A according to some example embodiments of the inventive concepts, detailed description of these components will be omitted.

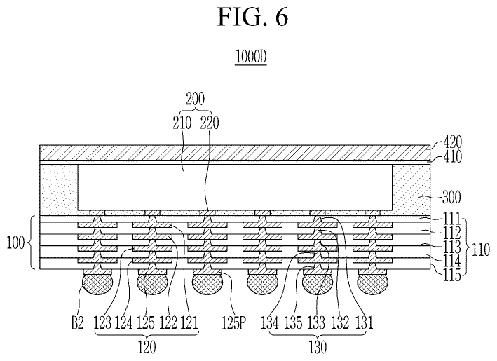

FIG. 6 is a cross-sectional view of a semiconductor package according to some example embodiments of the present disclosure.

Referring to the drawings, the semiconductor chip 200 may be connected by directly contacting the substrate 100.

For example, the connection pad 220 of the semiconductor chip 200 may directly contact the first via 131 that penetrates the first insulating layer 111 positioned closest to the semiconductor chip 200 in the insulating layer 110 of the substrate 100, and may be electrically connected to the wiring layer 120.

The substrate 100 may be formed by sequentially forming an insulating layer and a wiring layer on the semiconductor chip 200. For example, the substrate 100 may include the first insulating layer 111, the first wiring layer 121 disposed on the first insulating layer 111, the second insulating layer 112 disposed on the first insulating layer 111 to cover the first wiring layer 121, the second wiring layer 122 disposed on the second insulating layer 112, the third insulating layer 113 disposed on the second insulating layer 112 to cover the second wiring layer 122, the third wiring layer 123 disposed on the third insulating layer 113, the fourth insulating layer 114 disposed on the third insulating layer 113 to cover the third wiring layer 123, the fourth wiring layer 124 disposed on the fourth insulating layer 114, the fifth insulating layer 115 disposed on the fourth insulating layer 114 to cover the fourth wiring layer 124, and the fifth wiring layer 125 disposed on the fifth insulating layer 115.

The substrate 100 may include the first via 131 that electrically connects the first wiring layer 121 and the semiconductor chip 200 by penetrating the first insulating layer 111, the second via 132 that electrically connects the second wiring layer 122 and the first wiring layer 121 by penetrating the second insulating layer 112, the third via 133 that electrically connects the third wiring layer 123 and the second wiring layer 122 by penetrating the third insulating layer 113, the fourth via 134 that electrically connects the fourth wiring layer 124 and the third wiring layer 123 by penetrating the fourth insulating layer 114, and the fifth via 135 that electrically connects the fifth wiring layer 125 and the fourth wiring layer 124 by penetrating the fifth insulating layer 115.

Since the description of other components is the same as that described in the description of the semiconductor package 1000A according to some example embodiments of the inventive concepts, detailed description of these components will be omitted.

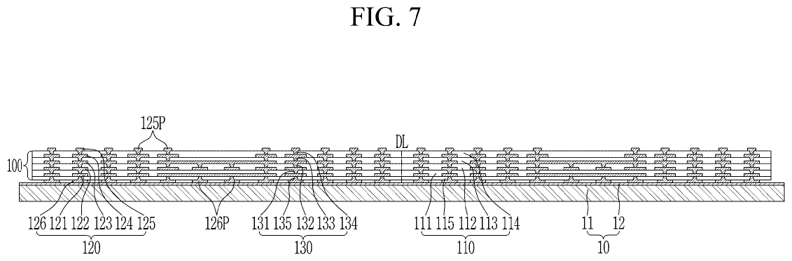

FIGS. 7 to 14 are diagrams for describing a manufacturing process of a semiconductor package according to some example embodiments of the inventive concepts.

A manufacturing method for a semiconductor package according to some example embodiments includes disposing the substrate 100 on a first carrier structure 10, disposing at least one semiconductor chip 200 on the substrate 100, molding the semiconductor chip 200 with a molding material 300, attaching a second carrier structure 400 including the sequentially stacked thermal conductive adhesive 410, the thermal conductive layer 420, the adhesive 430, and a base film 440 on the molding material 300 so that the thermal conductive adhesive 410 is attached to face the molding material 300, separating the first carrier structure 10 from the substrate 100, and debonding the adhesive 430 from the thermal conductive layer 420 of the second carrier structure 400.

As will be described later, the manufacturing method for a semiconductor package may include a dicing process for dividing the semiconductor package into individual packages. And in this specification, the same reference numerals are used for the substrate 100, the molding material 300, and the second carrier structure 400 before and after dicing.

First, referring to FIG. 7, the substrate 100 may be disposed on the first carrier structure 10. The first carrier structure 10 may include a base film 11 and an adhesive 12, and the substrate 100 may be fixed by being attached to the adhesive 12. For example, the substrate 100 may be attached to the first carrier structure 10.

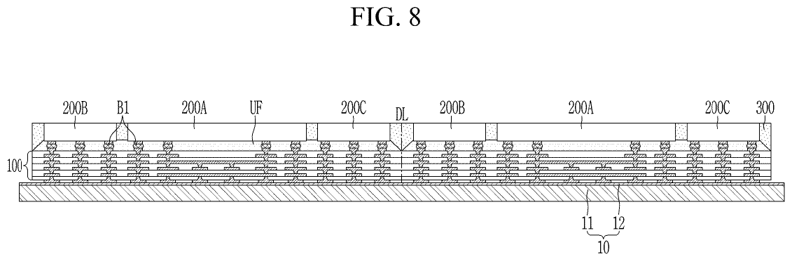

Next, referring to FIG. 8, at least one semiconductor chip 200 may be disposed on the substrate 100 and the semiconductor chip 200 may be molded with the molding material 300. For example, the at least one semiconductor chip 200 may be mounted on the substrate 100. The semiconductor chip 200 included in each semiconductor package may be disposed on each region of the substrate 100 distinguished by a dicing line DL, and may be included in an individual package through a later dicing process. For example, a first semiconductor chip 200A, a second semiconductor chip 200B, and a third semiconductor chip 200C may be disposed on each region of the substrate 100 distinguished by the dicing line DL. The molding of the semiconductor chip 200 with the molding material 300 may use known methods such as compression molding and transfer molding.

As described above, a first surface of the semiconductor chip 200 may be exposed to (e.g., at) a first surface of the molding material 300, and for this purpose, a grinding of the molding material 300 may be performed after the semiconductor chip 200 is molded with the molding material 300. When grinding the molding material 300, a portion of the semiconductor chip 200 may be ground together.

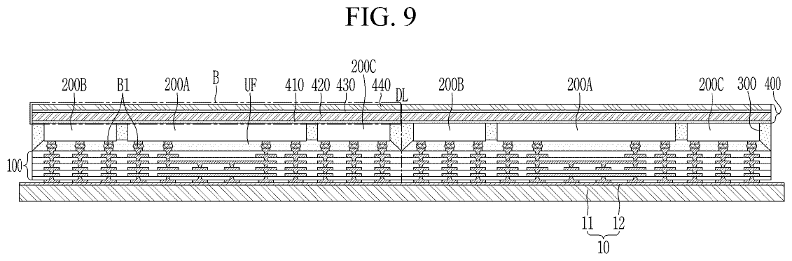

Next, referring to FIG. 9, the second carrier structure 400 including the sequentially stacked thermal conductive adhesive 410, the thermal conductive layer 420, the adhesive 430, and the base film 440 may be attached on the semiconductor chip 200 and the molding material 300 so that the thermal conductive adhesive 410 faces the semiconductor chip 200 and the molding material 300.

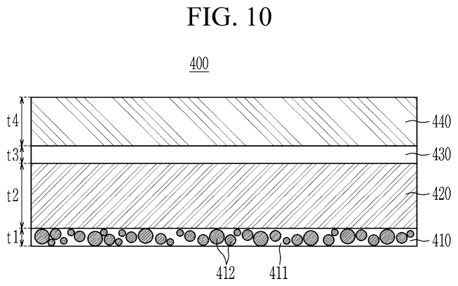

Referring to FIG. 10, the second carrier structure 400 may include the thermal conductive adhesive 410, the thermal conductive layer 420 disposed on the thermal conductive adhesive 410, the adhesive 430 disposed on the thermal conductive layer 420, and the base film 440 disposed on the adhesive 430. Each component of the second carrier structure 400 may use a material having heat resistance (e.g., at 300° C. or higher), chemical resistance, and pressure resistance (e.g., at 200 KN or higher).

As described above, a material that has excellent adhesion to the body 210 and the molding material 300 of the semiconductor chip 200, and has thermal conductivity may be used as the material for the thermal conductive adhesive 410. The thermal conductive adhesive 410 may include the matrix resin 411 and the thermal conductive filler 412. The matrix resin 411 may include, for example, an acrylic resin with excellent durability. The thermal conductive filler 412 may exist dispersed in the matrix resin 411, and the thermal conductive filler 412 particles adjacent to each other may form the heat dissipation path tp that transfers heat emitted from the semiconductor chip 200 to the thermal conductive layer 420. The thermal conductive filler 412 may include, for example, alumina (Al₂O₃), but is not limited thereto, and may include metals such as copper, aluminum, and silver.

The thickness t1 of the thermal conductive adhesive 410 may be 10 μm to 50 μm. According to the present disclosure, by using a tape-type second carrier structure 400 including the thermal conductive adhesive 410, the thermal conductive layer 420, the adhesive 430, and the base film 440, it is possible to apply the thermal conductive adhesive 410 having a low thickness compared to a heat dissipation paste to the semiconductor package 1000A. Therefore, according to the present disclosure, it is possible to increase the thickness of the thermal conductive layer 420 compared to a semiconductor package of the same size, and improve the heat dissipation characteristics of the semiconductor package.

A material with high thermal conductivity, such as metal, may be used as a material for the thermal conductive layer 420. For example, the thermal conductive layer 420 may include at least one of copper, aluminum, and stainless steel (SUS).

The thickness t2 of the thermal conductive layer 420 may be 10 μm to 200 μm. If the thickness t2 of the thermal conductive layer 420 is too low, the heat dissipation effect may be minimal, and if the thickness t2 of the thermal conductive layer 420 is too high, the entire thickness of the semiconductor package 1000A may increase. Therefore, in some example embodiments the thickness t2 of the thermal conductive layer 420 may be within the above-mentioned range.

As the material for the adhesive 430, a material may be used that is adhesive, is easy to debond from the thermal conductive layer 420, and does not leave a residue after debonding.

In some example embodiments a material with excellent heat resistance and chemical resistance may be used as the material for the adhesive 430. For example, the adhesive 430 may include an acrylic resin, but is not limited thereto. The thickness of the adhesive 430 may be 10 μm to 30 μm.

Materials for the base film 440 may be materials having excellent heat resistance, chemical resistance, and mechanical characteristics. The base film 440 may include at least one of polyimide (PI), polyethylene naphthalate (PEN), and polyether ether ketone (PEEK).

The thickness of the base film 440 may be 50 μm to 300 μm.

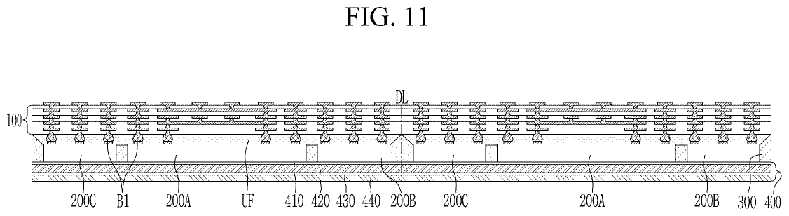

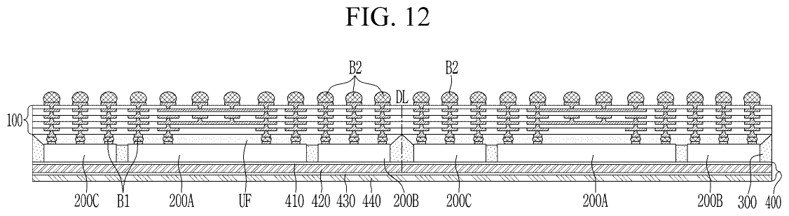

Next, referring to FIGS. 11 and 12, the first carrier structure 10 may be separated from the substrate 100 and the conductive bump B2 may be attached on the substrate 100. The first carrier structure 10 may be separated by debonding the adhesive 12 from the substrate 100 by, for example, laser ablation, mechanical peeling, ultraviolet irradiation, or heat treatment.

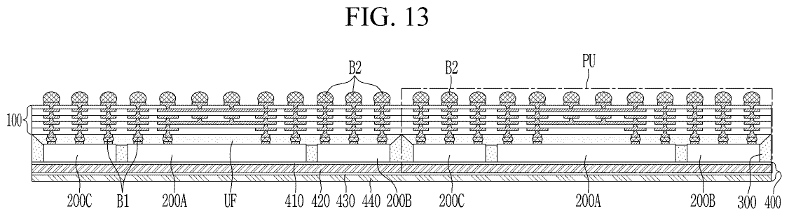

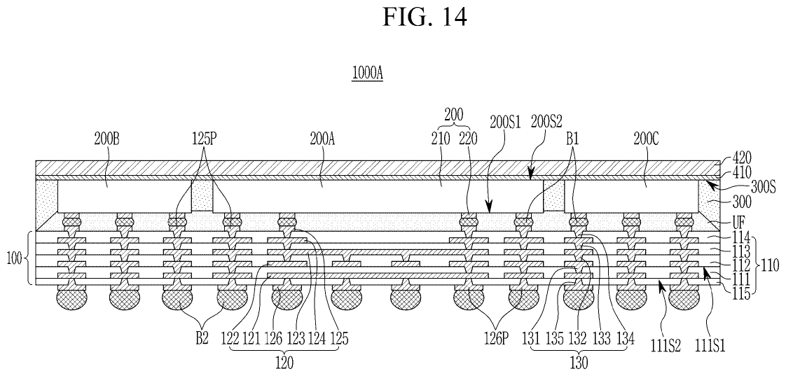

Next, referring to FIGS. 13 and 14, it is possible to form individual package units PU by dicing the substrate 100, the molding material 300, the thermal conductive adhesive 410, and thermal conductive layer 420 along the dicing line DL positioned between the semiconductor chips, and debonding the adhesive 430 from the thermal conductive layer 420 of the second carrier structure 400.

As shown in the drawings, only the substrate 100, the molding material 300, the thermal conductive adhesive 410, and the thermal conductive layer 420 may be diced, and the adhesive 430 and the base film 440 may not be diced. Thereafter, by debonding the adhesive 430 from the thermal conductive layer 420, each of the individual package units PU may be separated from the adhesive 430 and picked up. The dicing process may be performed, for example, through mechanical drilling, laser processing, or the like. The debonding of the adhesive 430 from the thermal conductive layer 420 of the second carrier structure 400 may be performed by, but is not limited to, laser ablation using UV wavelengths, and may also be performed by mechanical peeling, ultraviolet irradiation or heat treatment.

While some example embodiments of the inventive concepts have been described in detail, it is to be understood that the inventive concepts are not limited to the disclosed example embodiments, but on the contrary, are intended to cover various modifications and equivalent arrangements included within the spirit and scope of the appended claims.

What is claimed is:

1. A semiconductor package, comprising:
a substrate;
a semiconductor chip on the substrate, the semiconductor chip being electrically connected to the substrate;
a molding material on the substrate, the molding material molding the semiconductor chip;
a thermal conductive adhesive on the semiconductor chip and the molding material; and
a thermal conductive layer on the thermal conductive adhesive, a first surface of the thermal conductive layer facing the thermal conductive adhesive,
wherein a second surface of the thermal conductive layer has a surface roughness value higher than a surface roughness value of the first surface of the thermal conductive layer, the first surface being opposite the second surface.

2. The semiconductor package of claim 1, wherein
the surface roughness value of the second surface of the thermal conductive layer is 5 to 17 times the surface roughness value of the first surface of the thermal conductive layer.

3. The semiconductor package of claim 1, wherein
the surface roughness value of the second surface of the thermal conductive layer is 0.5 μm or more and 1.2 μm or less.

4. The semiconductor package of claim 1, wherein
the surface roughness value of the first surface of the thermal conductive layer is 0.03 μm or more and 0.2 μm or less.

5. The semiconductor package of claim 1, wherein
the thermal conductive adhesive comprises a matrix resin and a thermal conductive filler.

6. The semiconductor package of claim 1, wherein
a thickness of the thermal conductive adhesive is 10 μm to 50 μm.

7. The semiconductor package of claim 1, wherein
a thickness of the thermal conductive layer is 10 μm to 200 μm.

8. The semiconductor package of claim 1, wherein
a thermal conductivity of the thermal conductive adhesive and the thermal conductive layer is 148 W/mK or more.

9. The semiconductor package of claim 1, wherein
a coefficient of thermal expansion of the thermal conductive adhesive and the thermal conductive layer is 3 to 50 ppm/° C.

10. The semiconductor package of claim 1, wherein
a first surface of the semiconductor chip is exposed from the molding material at a same level as a first surface of the molding material, the first surface of the semiconductor chip being covered with the thermal conductive adhesive.

11. The semiconductor package of claim 10, wherein
a connection pad on a second surface of the semiconductor chip faces the substrate, the second surface of the semiconductor chip being opposite the first surface of the semiconductor chip.

12. A semiconductor package, comprising:
a substrate;
a first semiconductor chip and a second semiconductor chip on the substrate, the first semiconductor chip and the second semiconductor chip being spaced apart from each other;
a molding material on the substrate, the molding material molding the first semiconductor chip and the second semiconductor chip;
a thermal conductive adhesive on the first semiconductor chip, the second semiconductor chip, and the molding material; and
a thermal conductive layer on the thermal conductive adhesive, a first surface of the thermal conductive layer facing the thermal conductive adhesive,
wherein the substrate electrically connects the first semiconductor chip and the second semiconductor chip to each other,
and a second surface of the thermal conductive layer has a surface roughness value higher than a surface roughness value of the first surface of the thermal conductive layer, the first surface being opposite the second surface.

13. The semiconductor package of claim 12, wherein
the first semiconductor chip is an application specific integrated circuit, and the second semiconductor chip is a high bandwidth memory chip.

14. The semiconductor package of claim 12, wherein
the surface roughness value of the second surface of the thermal conductive layer is 0.5 μm or more and 1.2 μm or less.

15. The semiconductor package of claim 12, wherein
the surface roughness value of the first surface of the thermal conductive layer is 0.03 μm or more and 0.2 μm or less.

16. A manufacturing method of a semiconductor package, comprising:
molding at least one semiconductor chip with a molding material, the at least one semiconductor chip being on a substrate, and the substrate being on a first carrier structure;
attaching a second carrier structure on the at least one semiconductor chip and the molding material,
the second carrier structure including a thermal conductive adhesive, a thermal conductive layer, an adhesive, and a base film sequentially stacked, and the thermal conductive adhesive is attached facing the semiconductor chip and the molding material;
separating the first carrier structure from the substrate; and
debonding the adhesive from the thermal conductive layer of the second carrier structure.

17. The manufacturing method of a semiconductor package of claim 16, wherein
the debonding of the adhesive is performed by laser ablation, mechanical peeling, ultraviolet irradiation, or heat treatment.

18. The manufacturing method of a semiconductor package of claim 16, further comprising:
dicing the substrate, the molding material, the thermal conductive adhesive, and the thermal conductive layer along a dicing line positioned between semiconductor chips of the at least one semiconductor chip, after the separating of the first carrier structure.

19. The manufacturing method of a semiconductor package of claim 16, wherein
the adhesive comprises an acrylic-based resin.

20. The manufacturing method of a semiconductor package of claim 16, wherein
the base film comprises at least one of polyimide, polyethylene naphthalate, and polyether ether ketone.
